(19) United States
(12) Patent Application Publication
(10) Pub. No.: US 2007/0117324 A1
(43) Pub. Date: May 24, 2007

(54) Vertical MOS transistor and fabrication process

(76) Inventor: Bernard Previtali, Grenoble (FR)

Correspondence Address: LOWE HAUPTMAN GILMAN & BERNER, LLP, 1700 DIAGNOSTIC ROAD, SUITE 300, ALEXANDRIA, VA, 22314, US

(21) Appl. No.: 11/529,315

(22) Filed: Sep. 29, 2006

(30) Foreign Application Priority Data
Sep. 30, 2005 (FR) 05 10022

(51) Int. Cl. H01L 21/336; H01L 29/94

(52) U.S. Cl. 438/264; 257/302

(57) ABSTRACT

The invention relates to a vertical field-effect transistor. It comprises an island (12) of doped single-crystal semiconductor material, comprising a drain region (15) and a drain contact region (17) placed laterally with respect to the drain region, and above the island, a source region (38) and several vertical parallel channels (36) made of a lightly-doped single crystal semiconducting material, which extends vertically between the drain region and the source region and each channel being completely surrounded by an insulating sheath (46), and the space that separates the channels thus isolated from one another being filled with a conducting gate (50) each enclosing channels. The invention also relates to a novel fabrication process using a sacrificial gate layer whose thickness defines the length of the channel.

### RELATED APPLICATION

The present application is based on, and claims priority from, France Application Number 05 10022, filed Sep. 30, 2005, the disclosure of which is hereby incorporated by reference herein in its entirety.

### FIELD OF THE INVENTION

The invention relates to insulated-gate field-effect transistors (MOS transistors) and more particularly to what are called “vertical” transistors, the particular feature of which is that they include a drain region and a source region located one on top of the other, with a very short semiconductor channel formed by the thickness of a semiconductor layer between the source and the drain. The channel is associated with a control gate, which permits or prevents a current to flow between the source and the drain.

### BACKGROUND OF THE INVENTION

A vertical transistor has the advantage of a very short channel length since this length may be defined by the thickness (which is very well controlled and may be very small) of a semiconductor layer, whereas in “horizontal” transistors the channel length can be defined only by photolithographic masking. Photolithographic masking has an intrinsic resolution limit tied to the wavelength used. In optical photolithography, it is barely possible to go down below a few tenths of a micron, whereas it would be advantageous to go down to a few tens of nanometres, or even less. A short channel length allows the transistor to operate very rapidly, which is becoming increasingly desirable in many applications.

In addition, a vertical transistor may in general be more compact than a horizontal transistor since the source is located above or below the drain and not alongside the drain.

The article “Selectively grown vertical Si MOS transistor with reduced overlap capacitances” by D. Klaes and al., in the journal Thin Solid Films 336 pages 306-308 (1998), Patent Application FR A1-2 810 792, and Patent U.S. Pat. No. 6,518,622 describe vertical transistors. However, these transistors are not optimized from the standpoint of:

footprint;

capability of transmitting sufficient current through the channel, while still properly controlling this current via the gate; and

parasitic capacitances that exist between gate and drain or gate and source, which limit the operating speed of the transistor.

One important transistor performance parameter is in particular the ratio of the current in the on state to the leakage current in the off state. This ratio should preferably be at least 1000, but it tends to be degraded when the gate length is reduced.

Other problems may be encountered, such as the difficulty of forming and controlling the contact with the control gate of the transistor, or the quality of the resistance for access to the source and to the drain of the transistor.

To optimize the performance of vertical field-effect transistors the present invention proposes a novel vertical transistor structure and a novel fabrication process.

### SUMMARY OF THE INVENTION

The fabrication process according to the invention comprises the following steps:

a) an island of semiconductor material (in particular silicon or germanium, or a silicon/germanium alloy), forming a drain region laterally adjacent to a drain contact region, is defined;

b) at least one layer, called a sacrificial gate layer, the thickness of which defines the length of the channels that separate the drain region from a source region lying above the drain region, is deposited;

c) vertical holes are drilled in the sacrificial gate layer, above the drain region and down to the surface of the semiconductor material of this region;

d) lightly-doped semiconductor material is grown epitaxially in the holes from the semiconductor material of the drain region, in order to form both vertical single-crystal semiconductor channels and the source region of the transistor;

e) the source region is doped;

f) the sacrificial gate layer is removed, leaving behind the channels of semiconductor material between the source region and the drain region, in a cavity surrounding these channels, and an insulating sheath is formed around each channel;

g) the cavity is filled with a conducting material forming a definitive gate isolated from the channels by the insulating sheaths; and

h) interconnects in contact with the drain contact region, with the source region and with the definitive gate are formed.

Preferably, step b) includes the deposition of an insulating layer (preferably a silicon nitride, but possibly also a silicon oxide or germanium nitride, layer) before the deposition of the sacrificial gate layer, and the deposition of another insulating (silicon nitride) layer after deposition of the sacrificial gate layer. These layers serve as barriers during the subsequent selective etching steps.

Preferably, the sacrificial gate layer is etched in step b) so as to cover the drain region and a gate contact region external to the island of semiconductor material, but not covering the drain contact region.

To make the subsequent etching of the metal interconnects easier a step of depositing an insulating planarization layer after the sacrificial gate layer has been etched may be provided before step c).

The drilling of the narrow parallel channels right through the entire thickness of the sacrificial gate layer is preferably carried out using an electron beam lithography.

Two major variants of the process according to the invention may be envisaged: in a first variant, the material of the sacrificial gate layer is amorphous or polycrystalline silicon or a similar oxidizable material such as a silicon/germanium compound; in a second variant, the material of the sacrificial gate layer is silicon oxide.

In step f), an insulating sheath around each channel is preferably formed after the sacrificial gate layer has been removed.

It may be noted that it is possible to form two transistors of opposite type namely, NMOS and pMOS, having a common drain region, a common gate and separate sources, on any one silicon island, thus producing an inverter based on complementary transistors.

Apart from the novel fabrication process indicated above, the present invention also relates to a novel vertical field-effect transistor structure. This transistor comprises an island of doped single-crystal semiconductor material comprising a drain region and a drain contact region placed laterally with respect to the drain region, and above the island, a source region and several vertical parallel channels made of a lightly-doped single-crystal semiconductor material, which extends vertically between the drain region and the source region, each channel being completely surrounded by an insulating sheath, and the space separating the channels thus isolated from one another being filled with a conducting gate each surrounding the channels.

Preferably, the gate extends above the drain region but not above the drain contact region.

### BRIEF DESCRIPTION OF DRAWINGS

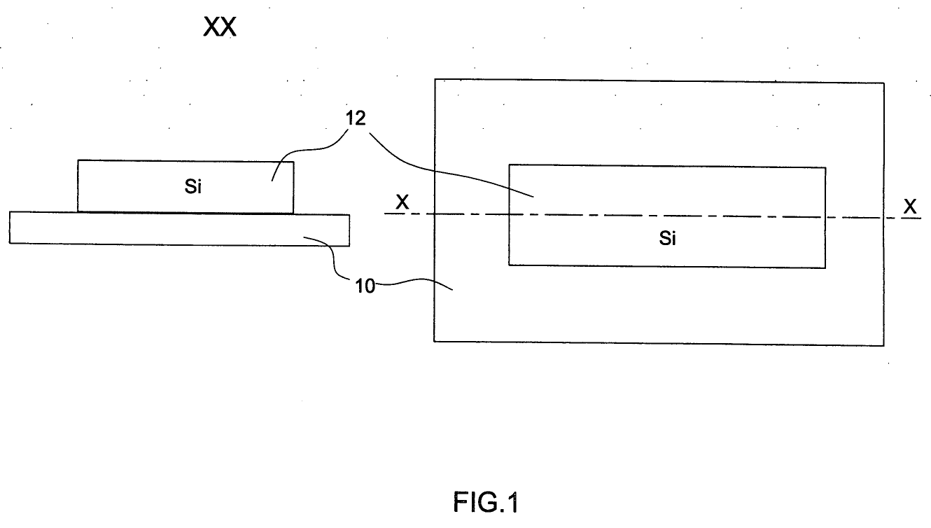

Other features and advantages of the invention will become apparent on reading the following detailed description which is given with reference to the drawings in which FIGS. 1 to 21 show the detailed successive steps of a preferred method of implementing the fabrication process according to the invention.

### DETAILED DESCRIPTION OF PREFERRED EMBODIMENTS

In general, in the following description, each figure comprises, for clarity of the explanations, both a top view and one or two sectional views on one or two axes namely the XX axis (horizontal in the figure) and/or YY (vertical in the figure) which are defmed in the top view. The drawings are not to scale, in order to make the diagrams easier to examine.

The process starts with a substrate 10 in which a semiconductor (generally silicon) active zone corresponding to the transistor to be produced is defmed.

In the example shown, it is assumed that the starting substrate is a substrate of the SOI (Silicon On Insulator) on which a single-crystal silicon island 12 is formed. It will also be possible to start with a silicon substrate and to define an insulating peripheral zone by the LOCOS process (local insulation by thermal oxidation of the silicon), this zone surrounding a silicon region in which the transistor will be formed. It will also be possible to delimit the island by an insulating peripheral trench in a silicon substrate.

The island could also be made of germanium or a germanium/silicon alloy.

This first step (FIG. 1) also serves to define the semiconductor region in which the transistor will be formed.

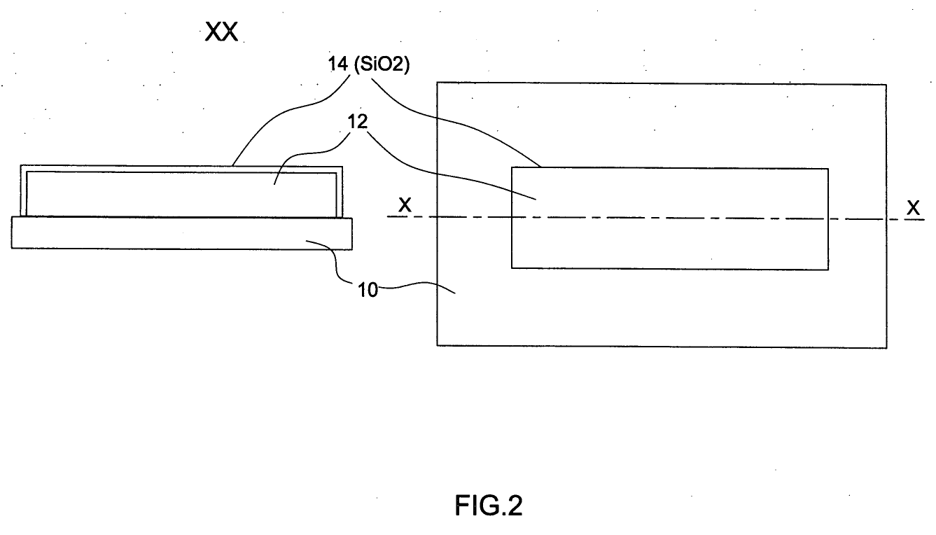

Next (FIG. 2), a thin insulating layer 14, preferably a silicon oxide layer, is deposited, which covers the entire silicon island, the sidewalls included. The oxide may be deposited or formed by thermal oxidation of the silicon.

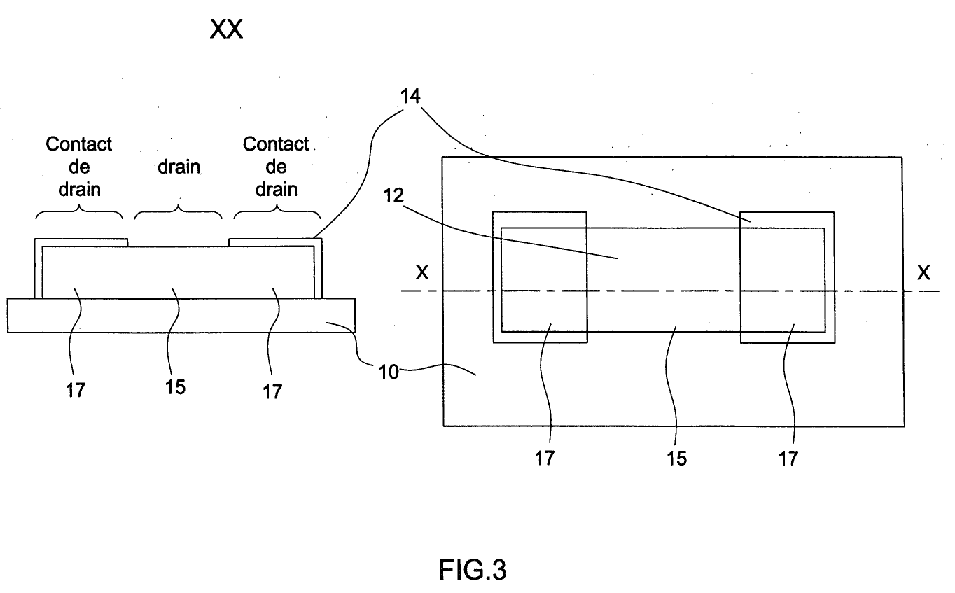

Part of the island 12 (in this example, the two ends, but it could be only one end, especially if it is desired to reduce the footprint) is then masked and the oxide in the unmasked region is removed (FIG. 3). The silicon region thus bared corresponds to a drain region 15 of the vertical transistor—the gate will be above the drain and the source will be above the gate. Hereafter, the region that is at the bottom will be called the “drain” while the region at the top will be called the “source”, it being understood that these terms are interchangeable since they relate to the use of the transistor and not to its construction.

The drain contacts will be subsequently formed on the part 17 that currently remains protected by the silicon oxide 14—this part 17 is laterally adjacent to the drain region 15 and will hereafter be called the “drain contact region”. It will be seen subsequently that the drain contact region will be preferably silicided (or germanided) in order to improve its electrical conductivity and to reduce the drain contact access resistances.

The figures show masking of both ends of a rectangular silicon strip, however, it would be possible to mask only one end, or, conversely to mask a complete periphery of the island if it has a square or circular shape.

The silicon of the island may be doped at various stages in order to be of n-type in the case of an nMOS transistor or p-type in the case of a pMOS transistor. If at the stage shown in FIG. 3, the silicon is not already sufficiently doped, a doping step is carried out, preferably by ion implantation. The implantation is of the n-type (arsenic, antimony, phosphorus, etc.) or p-type (boron) depending on the type of transistor to be produced. The implantation takes place both in the drain region 15 which is not protected by the oxide 14, and in the drain contact regions 17 which are protected by the oxide, the implantation then being carried out with a sufficient energy to pass through the oxide.

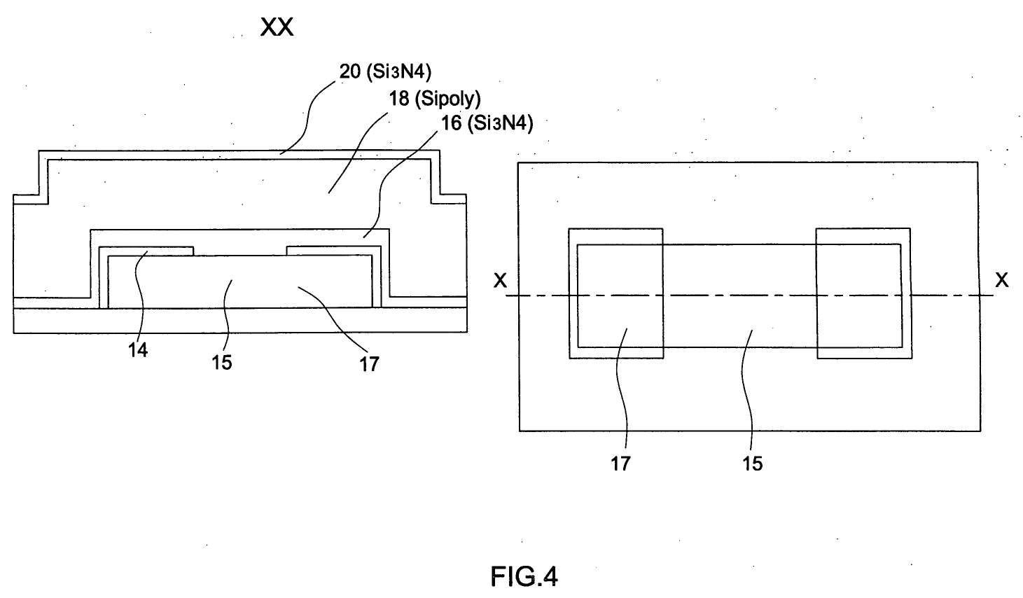

Next (FIG. 4) a silicon nitride insulating layer 16 is uniformly deposited, followed by an amorphous or polycrystalline silicon layer 18 and then a further silicon nitride insulating layer 20. The nitride layer 16 is very thin (preferably less than 5 nanometres), the layer 20 likewise.

The nitride layer 16 is a barrier layer, subsequently preventing the silicon 12 in the drain region from being etched while the layer 18 is being etched. The layer 16 is an insulating layer that acts as a spacer, because it keeps the drain region away from the channel regions (it limits short channel effects). Advantageously, it will be chosen so as to act as a stop layer in the subsequent etching operations. It also prevents oxygen from diffusing into the layer 15.

The nitride layer 20 serves as a layer for protecting the layer 18 of polycrystalline silicon while the latter is being etched.

The amorphous or polycrystalline silicon layer 18 is a sacrificial layer, also called hereafter the “sacrificial gate layer”—it is there temporarily and will be subsequently removed. Its thickness defines the length of the vertical semiconductor channels that will separate the drain from the source of the vertical transistor. This thickness may be a few tens of nanometres. It will be seen in another embodiment that this layer may be made of silicon oxide, which may simplify the fabrication. In what follows, it will be considered that this layer is made of polycrystalline silicon, the adjective “polycrystalline” being considered here as synonymous with “amorphous” when these two terms are considered as opposed to “single-crystal”. A silicon-germanium alloy may also be used, the advantage of the latter material being its very good etching selectivity with respect to silicon oxide and to silicon nitride.

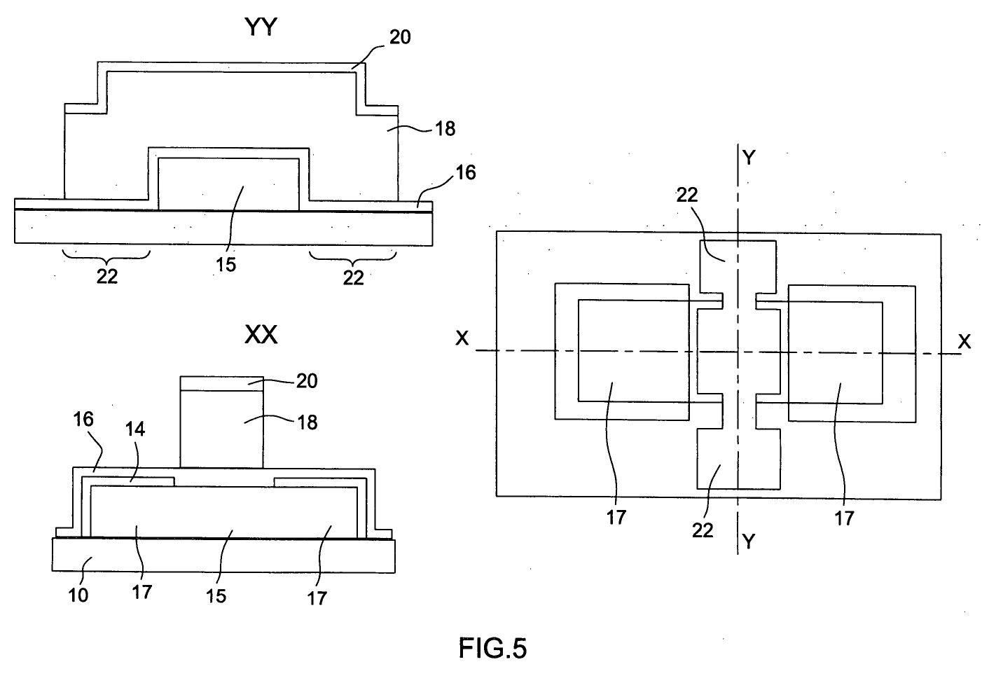

Next, (FIG. 5) the nitride layer 20 is etched using a photolithography resist mask, and then the silicon layer 18 is etched using the nitride mask 20 which remains, in order to remove said layers above the drain contact regions 17 (those which are covered with oxide 14) as may of course be clearly seen in the XX section in FIG. 5. The etching of the silicon is selective and stops on the nitride layer 16. The layers 18 and 20 are left not only above the actual drain region 15 but also on the substrate 10 in a region 22 which is not located above the silicon island 12, i.e. a region 22 which is neither above the drain region 15 nor above the drain contact region 17, as may of course be clearly seen in the top view and the YY section of FIG. 5. This gate region 22 on the substrate 10 will be used subsequently for forming a gate contact as will be seen later. The top view of FIG. 5 shows two gate contact regions 22, one on each side of the central drain region 15, which constitute lateral extensions of the gate beyond the drain region (15) and drain contact region (17). The presence of two gate contact regions makes the subsequent removal of the sacrificial gate layer easier.

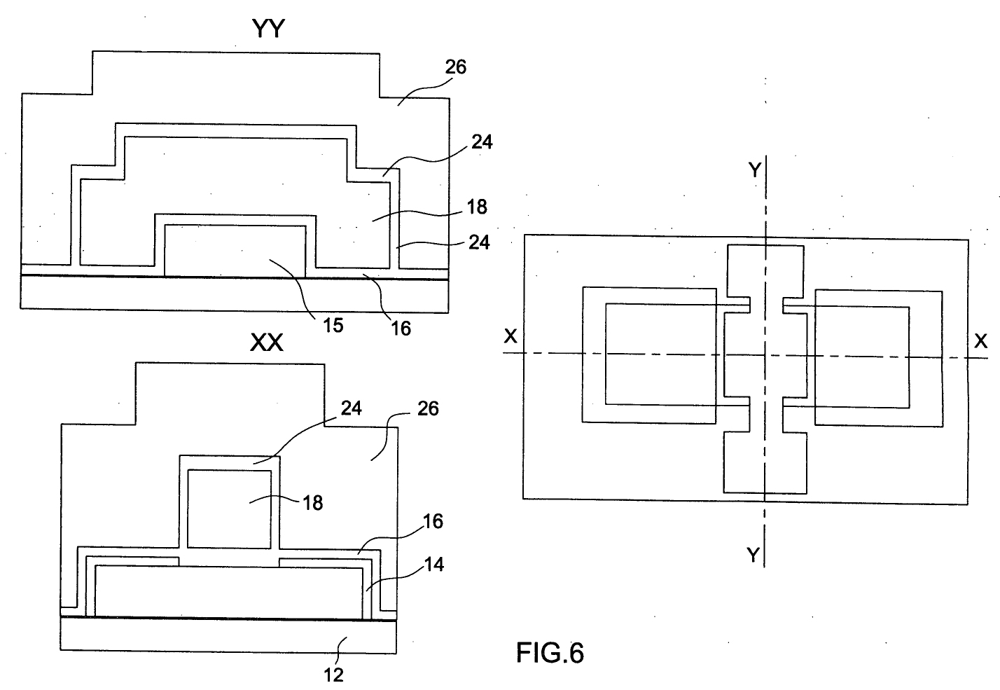

The next step (FIG. 6) consists in again covering the entire transistor with a silicon nitride layer 24 (which will serve as an etching stop layer) that covers the stripped part of the silicon layer 18, namely the sidewalls of this layer. The nitride layer 24 will constitute an etching stop layer during the subsequent operations. A silicon oxide layer 26 is then deposited. The oxide layer 26 is sufficiently thick to partly fill the recesses of the relief created by the lower layers, so that it is subsequently possible, by moving the excess oxide to planarize the relief present on the substrate.

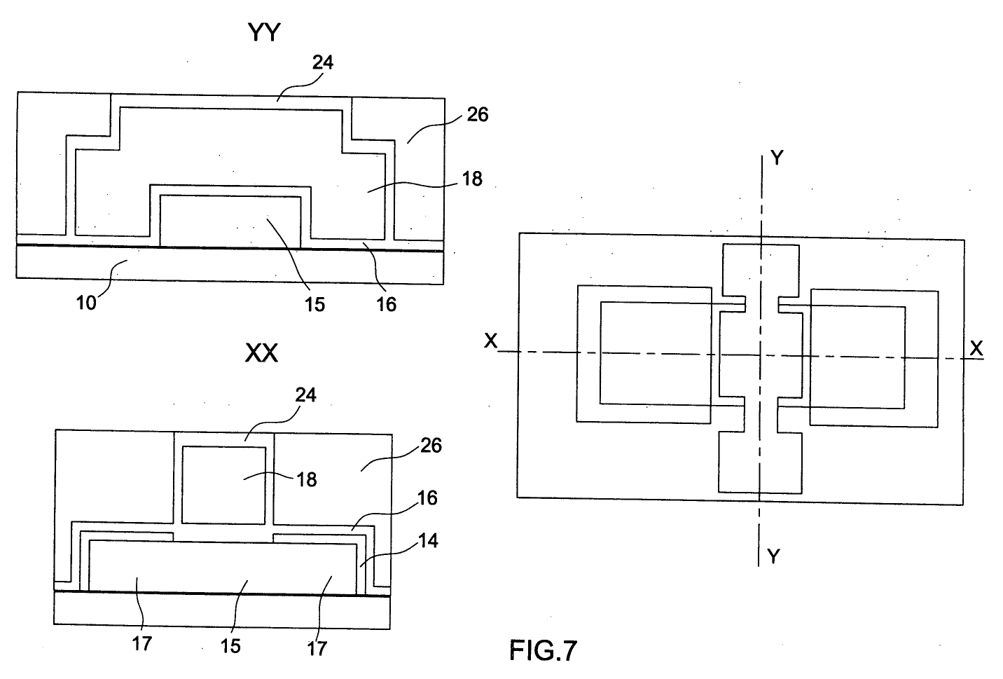

A planarization step is then carried out (FIG. 7). This comprises the physico-chemical etching of the oxide 26 so as to bare the silicon nitride 24 above the drain region 15 without removing the oxide in the recesses of the relief and especially without removing the oxide 26 above the drain contact regions 17.

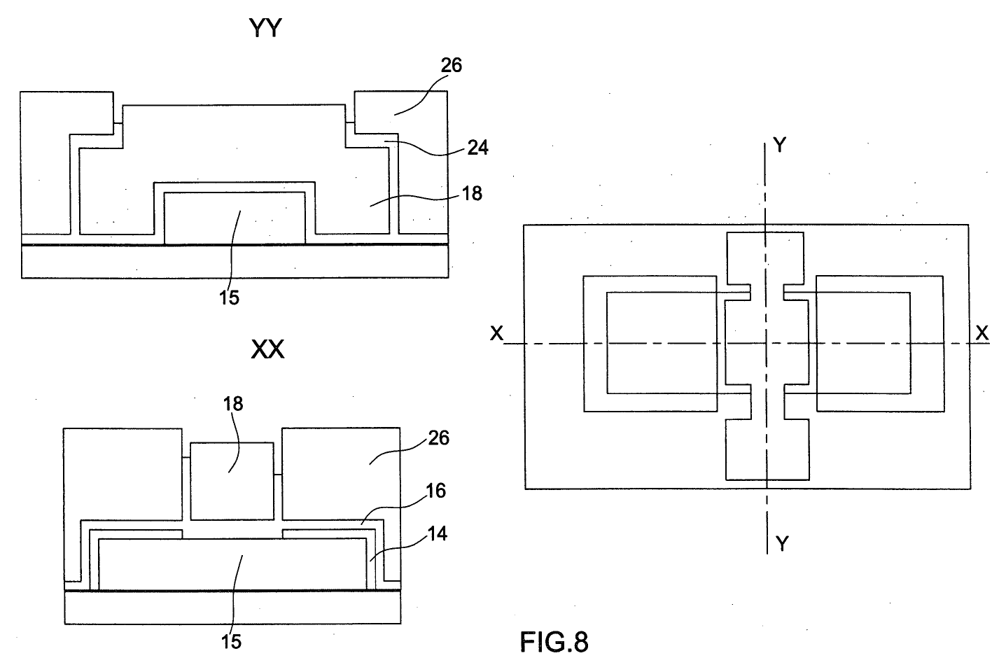

Next (FIG. 8) the residual nitride of the layer 24 at the point where it is not protected by the rest of the oxide layer 26, may be removed, bearing the sacrificial gate layer 18 only above the drain region 15.

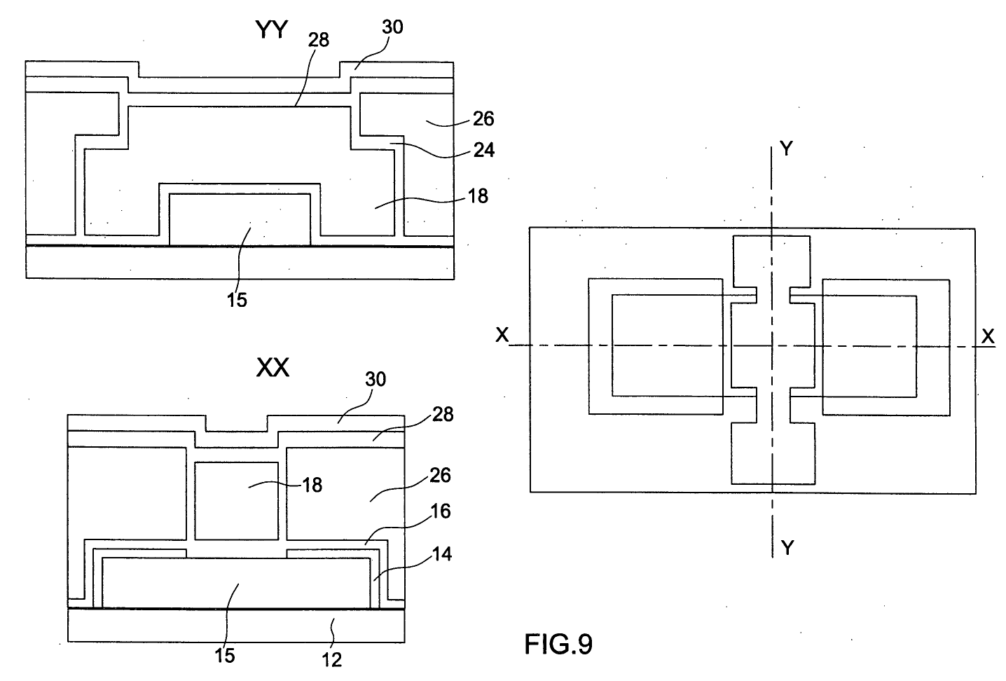

A very thin silicon nitride layer 28, followed by a silicon oxide layer 30 are deposited (FIG. 9), again uniformly. Preferably, the nitride layer 28 has approximately the same thickness as the nitride layer 16—less than 5 nanometres if possible. The oxide layer 30 will serve for protecting the nitride 28 when it will subsequently be necessary to etch the nitride of the layer 16 above the drain region.

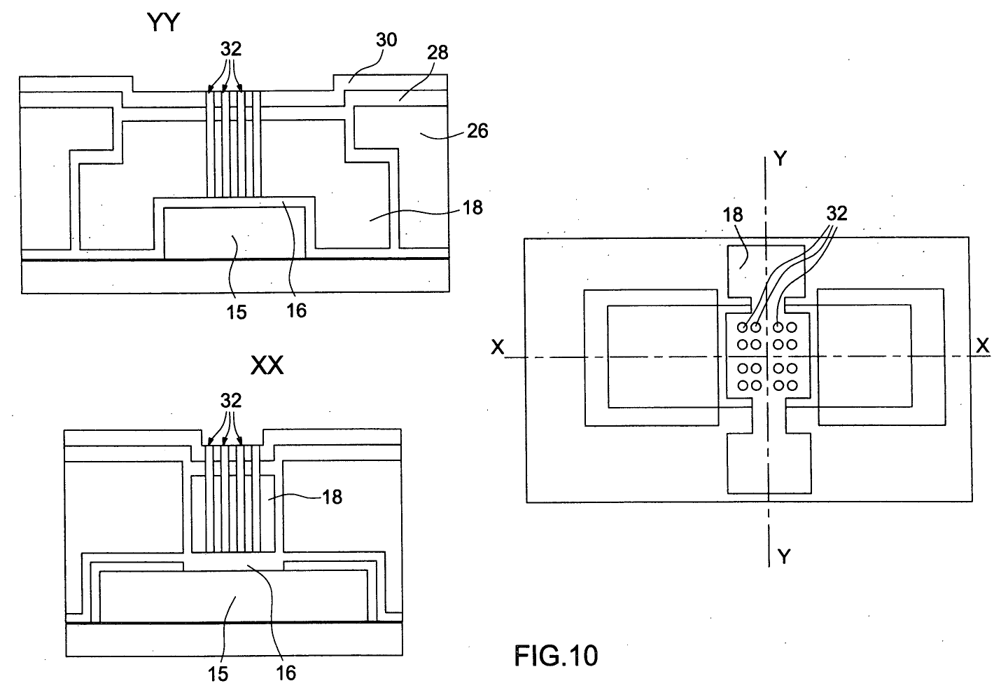

Next (FIG. 10), the essential step of etching vertical holes through the sacrificial gate layer 18 is carried out. These form a series of small diameter vertical parallel holes 32. The number of holes depends on the current that it is desired to pass through the transistor, a fraction of the current passing through each hole after these holes have been filled with semiconductor material constituting the channels of the transistor. The vertical holes are preferably etched using an electron beam through a photoetched resist mask. First the oxide layer 30 is etched, then the nitride layer 28 and then the polycrystalline silicon layer 18. The etching stops on the thin nitride layer 16 that protects the drain region.

What is therefore obtained is a sacrificial gate layer 18 through which vertical holes plumb with the drain region have been drilled, as may be seen in FIG. 10. The holes may have a diameter of about 40 nanometres. The semiconductor channels that will be formed in these holes will have a diameter even smaller than this value. By subdividing the channel of the transistor into several individual channels, each of which will be surrounded by an insulating sheath, and a control grid, makes it possible to improve the on-current/off-current ratio of the transistor.

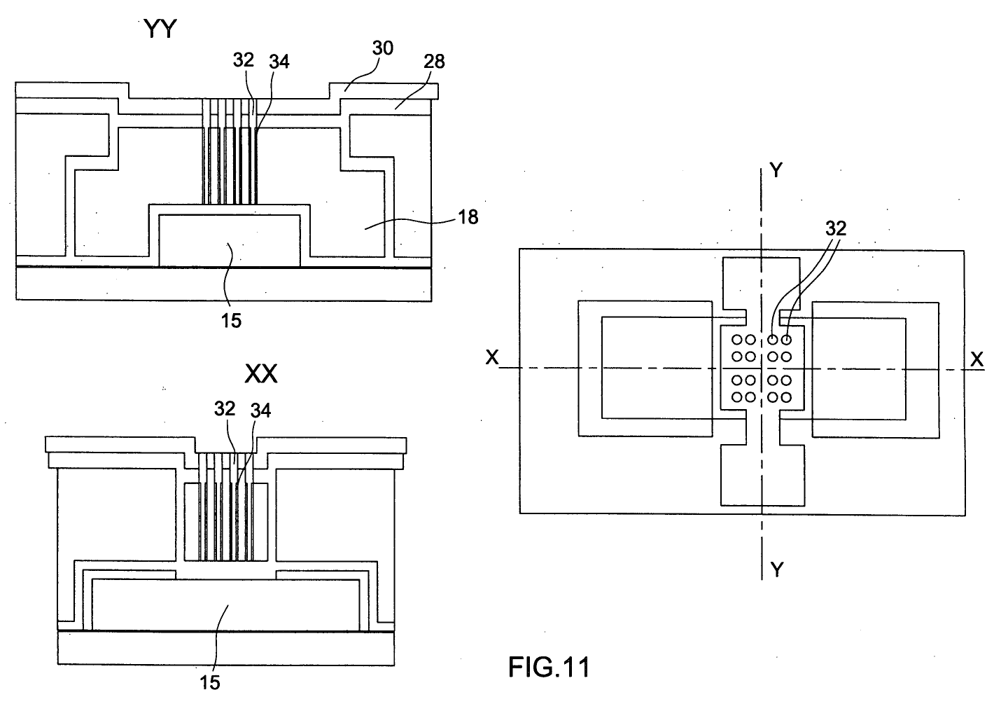

The next step (FIG. 11) consists in oxidizing the surface of the internal wall of the holes. The oxidation is a thermal oxidation of polycrystalline silicon 18, which allows the diameter of the holes 32 to be reduced. What are obtained are holes whose internal walls are covered with an insulating sheath 34 consisting of silicon oxide. This insulating sheath may be preserved, either definitively or temporarily. In the present example, it is preserved temporarily before another sheath is formed. This is because the insulating sheath 34 at this stage has a relatively large thickness and it is preferable for it to be subsequently replaced with a smaller thickness of gate insulator, which allows better control of the transistor. Typically, if it is desired to reduce the diameter of the channels to about 10 nanometres, an oxide layer of several tens of nanometres must be grown—such a thickness is too high to serve as gate insulator around each channel.

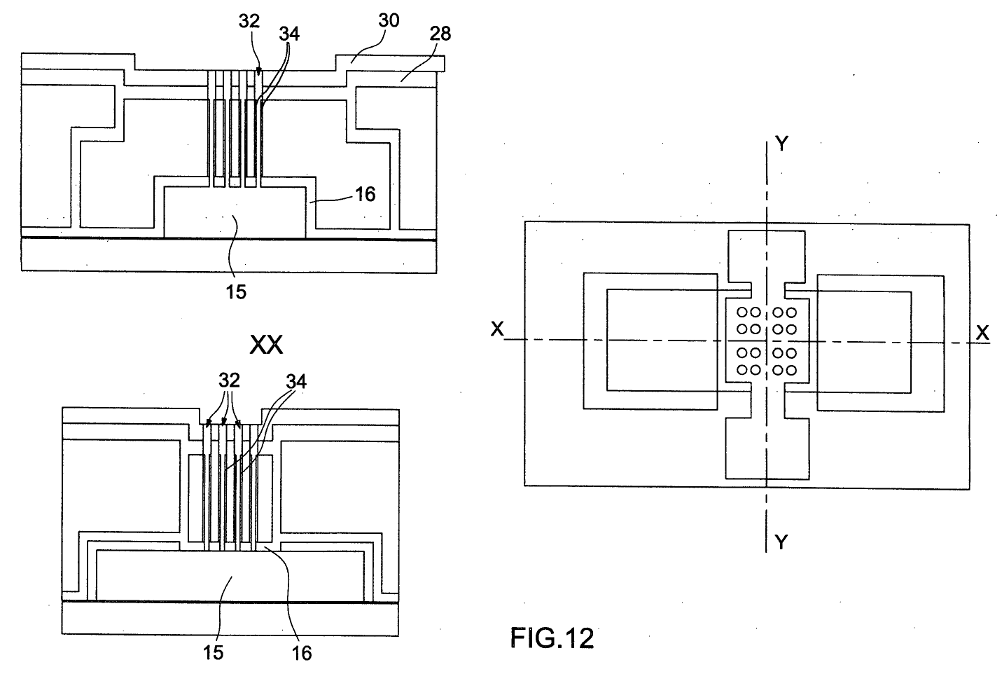

Next (FIG. 12), the nitride layer 16 which is bared at the bottom of the holes 32 is chemically etched. This etching bares the silicon of the drain of the bottom of the holes. At this stage, it is possible to dope or re-dope the drain region through the holes, with an impurity corresponding to the type of transistor to be produced, if the previous doping operations that were able to be carried out are insufficient.

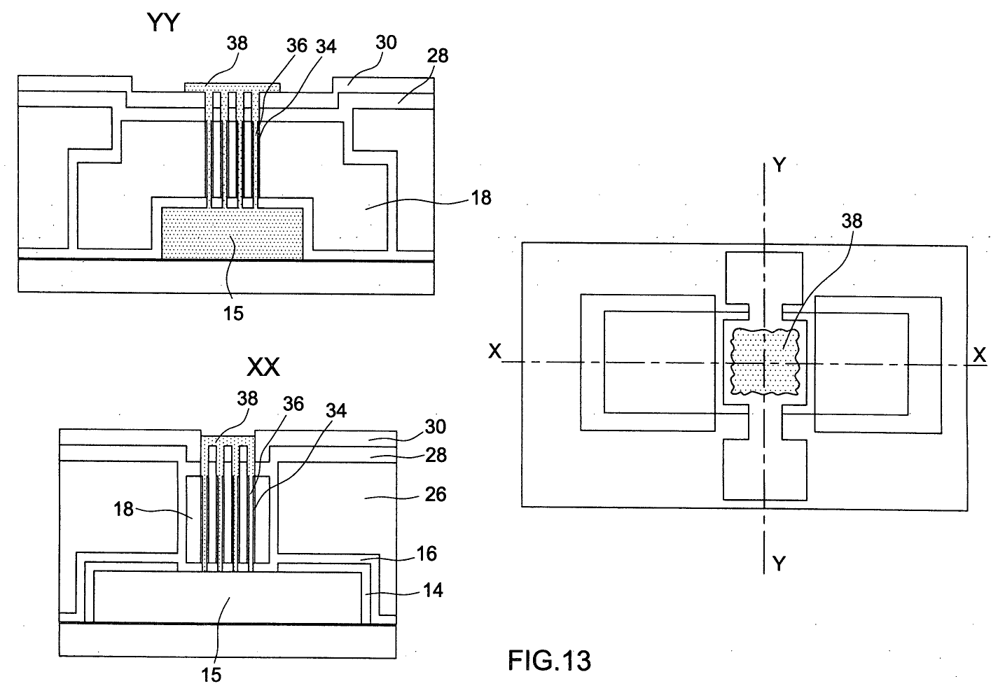

Next (FIG. 13), silicon is grown epitaxially inside the holes. The silicon, deposited by decomposition in the gas phase of a silicon precursor (generally silane) grows epitaxially from single-crystal nuclei that are formed by the silicon layer 12 bared in the bottom of the holes. The holes are filled with lightly-doped silicon (in practice, intrinsic or almost intrinsic silicon) constituting the semiconductor channels 36 of the MOS transistor. The channels 36 are covered with insulator (oxide 34) over their entire height. The epitaxial growth is carried out for a time long enough to also form, at the top, a continuous layer 38 which will, when doped, serve as source region. The semiconductor channels 36 therefore touch the drain 15 at the bottom and touch the source region 38 at the top.

At this stage, the source is then doped, with the same type of doping as the drain (but not necessarily with the same dose) by ion implantation in the thickness of the layer 38, without deep penetration into the channels 36.

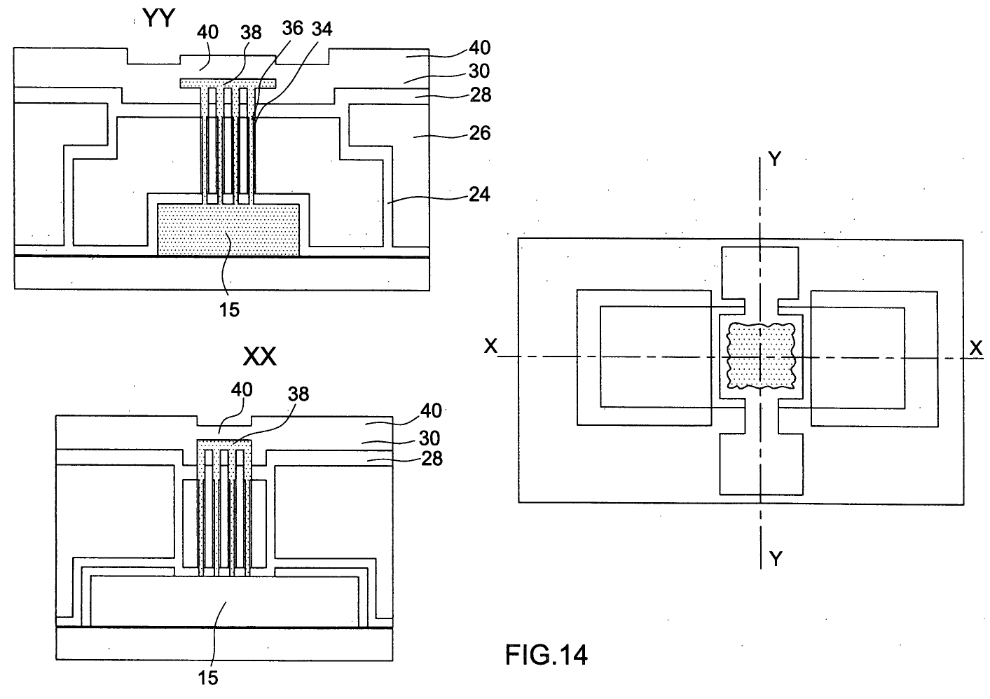

Having thus formed the source, its surface is protected with an oxide layer that is superposed on the layer 30 already present over the entire substrate (FIG. 14).

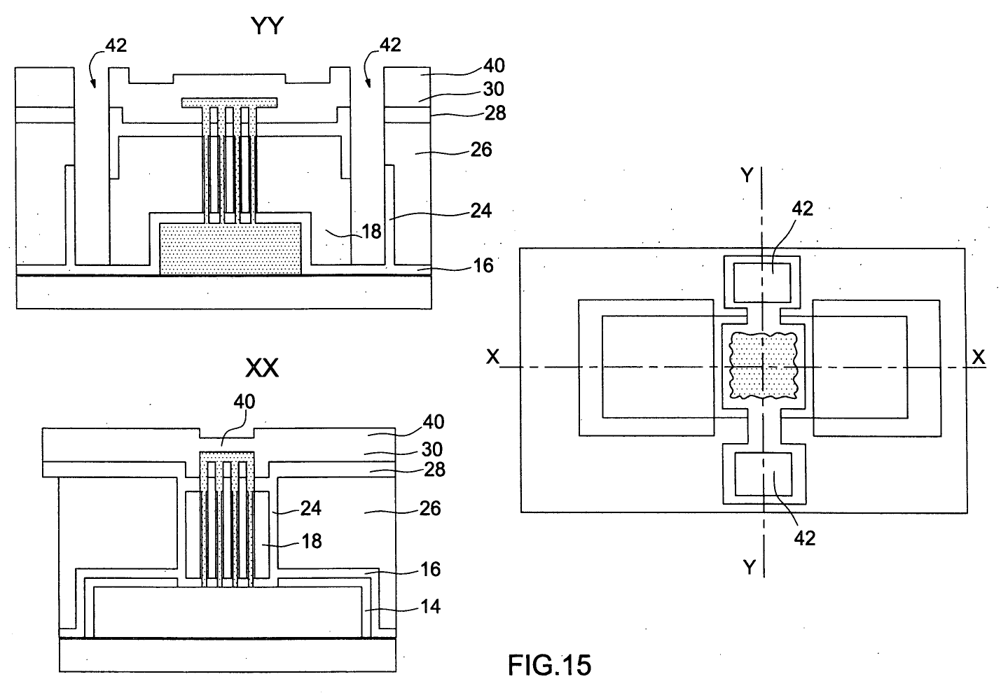

The following operations serve to completely remove the sacrificial gate layer in order to replace it with a definitive gate. These operations comprise a standard photolithography step (resist deposition, masking, irradiation and development) for opening the access holes 42 above the sacrificial gate, in the stack of layers 40, 30, 28, 26, 24, 18. These holes 42 are located outside the silicon island 12, and more precisely in the gate contact regions 22. The depth of the holes 42 is such that they reach the silicon nitride layer 16 which constitutes an etching stop layer in this hole-drilling operation (FIG. 15). In these operations, each etched layer serves as etching mask for the next layer, and the etchants are anisotropic and selective so as to etch a layer vertically and not laterally, so as not to etch the immediately subjacent layer.

The holes 42 will serve as a passage for removing the sacrificial gate material 18 and subsequently for replacing it with another, definitive material. It is preferable to have two holes 42, respectively on each side of the silicon island 12, in order to facilitate the extraction via these holes of the material making up the sacrificial layer.

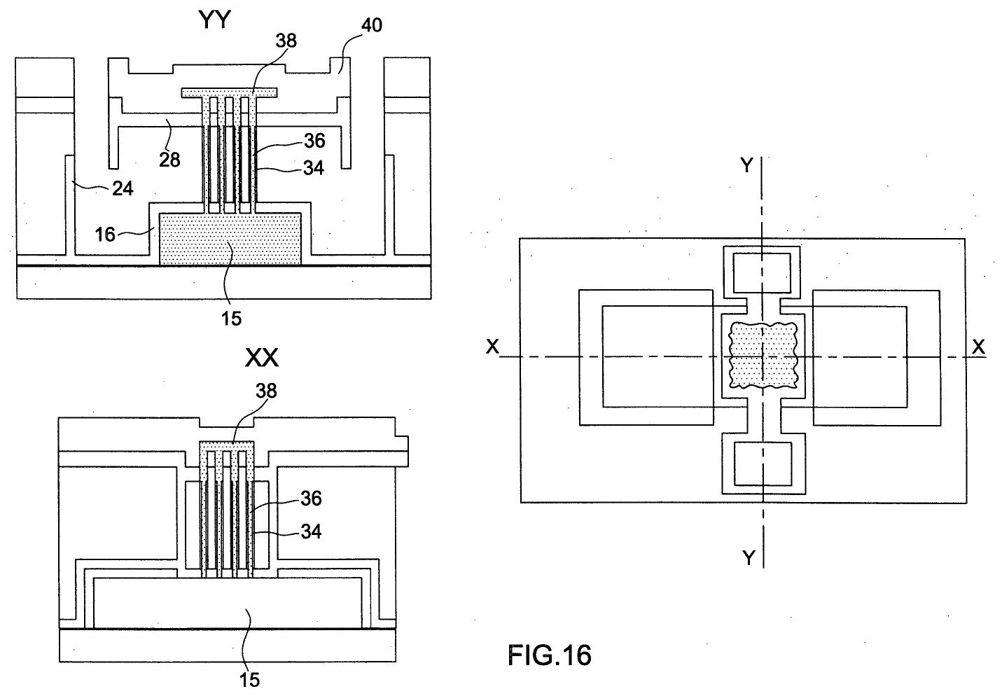

To remove the sacrificial gate layer 18, the polycrystalline silicon is anisotropically etched (FIG. 16) with an etchant that penetrates via the access holes 42. The etchant chosen is selective and damages neither the silicon nitride of the layer 16 nor the silicon oxide 34 that surrounds each channel 36. Removing the sacrificial layer leaves a cavity overhanging the drain region 15 and extending on either side of the latter in the regions 22. The channels 36, surrounded by their silicon oxide sheath 34 that protects them, remain in place between the source 38 and the drain 15 in the form of pillars that pass vertically through the cavity. The spacing of the channels and the diameter of the channels coated with their insulating sheath are such that a free space remains in practice between the adjacent insulated channels.

At this stage, it is considered that the insulating sheath 34 is too thick (several tens of microns in practice) to be able to serve as gate insulator in the final structure of the transistor, and this sheath will therefore be removed so as to be replaced with another insulating sheath which is thinner (a few nanometres at most, for example, about 1 nanometre). To do this a deoxidation operation is carried out which removes the oxide 34.

If desired, a further reduction of the thickness of the silicon channels 36 is carried out. In this case, the silicon of the channels is thermally oxidized and then the oxide formed is removed. Since this oxide has consumed part of the silicon thickness of the channels, their final thickness is reduced.

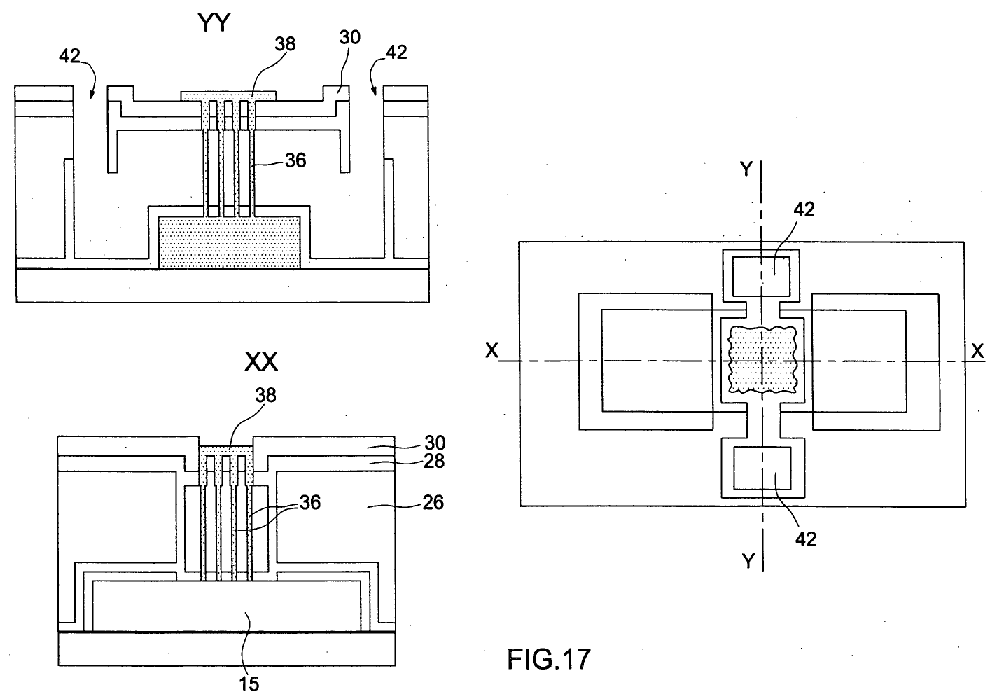

The thickness of silicon oxide 40 that had been added in order to protect the source before the operations for removing the sacrificial gate is also removed (FIG. 17). The source 38 is again bared. However, the entire oxide thickness present on the transistor is not removed so that the silicon oxide of the layer 30 remains beyond the source 38. If necessary, it is still possible at this stage to implant impurities into the source.

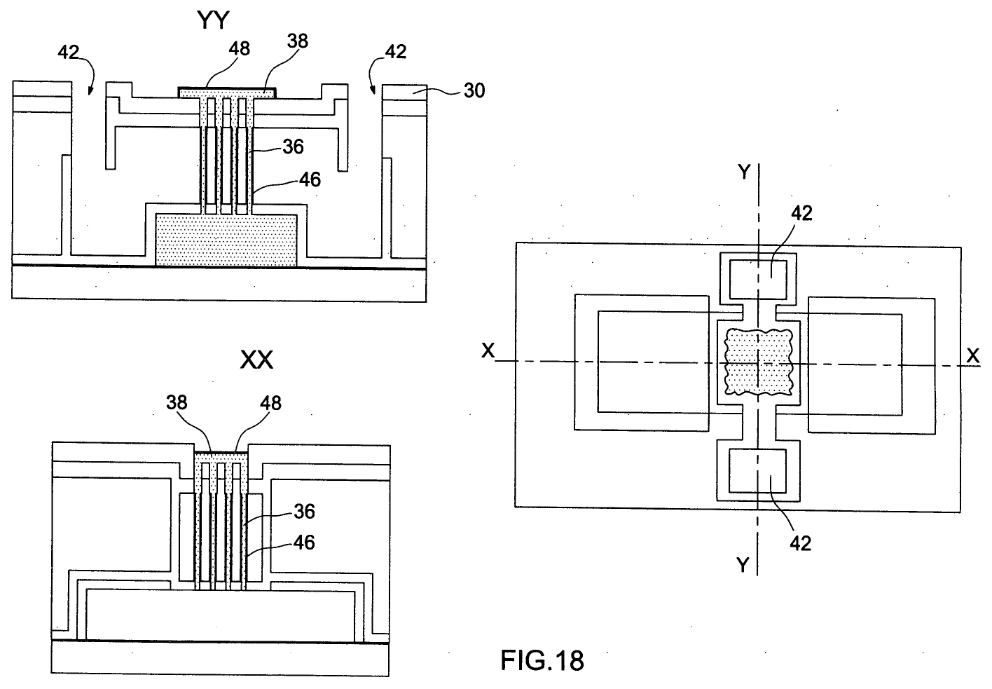

Next (FIG. 18) a thin insulating silicon oxide layer is deposited, which covers all the accessible parts, including inside the cavity left empty by removing the sacrificial gate. The insulator covers each of the channels 36 individually and then constitutes the definitive insulating sheath 46 of each of the channels 36. A free space remains between the various insulator-sheathed channels and this space will subsequently be filled with a conducting material constituting the gate of the transistor, so that the current conduction in each channel will be perfectly controlled by the gate through a very small thickness of gate insulator 46.

The layer of insulator constituting the insulating sheath 46 also causes a thin insulating layer 48 to be deposited on the source 38 and will subsequently protect the latter during etching of the definitive gate.

It should be noted that the insulator 46 or 48 could be formed by thermal oxidation of the silicon rather than by oxide deposition.

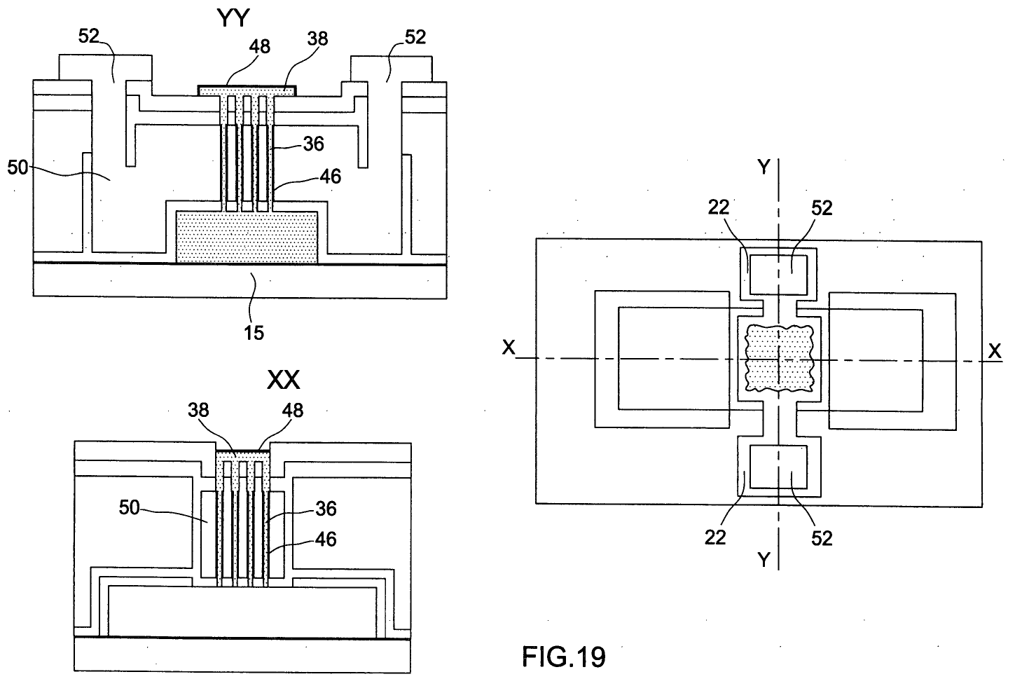

Next (FIG. 19) a definitive gate material 50 is deposited, which fills this entire cavity by passing through the holes 42 via which the sacrificial gate was removed. This material may especially be doped polycrystalline silicon, or titanium nitride. Next, a photolithography step carried out on the gate material 50 allows the gate contacts 52 outside the cavity to be defmed, by removing most of the gate material that then covers the entire substrate. The gate contacts are located above the regions 22 defined with reference to FIG. 5. The source 38 remains protected by the oxide 48 while this gate material is being removed.

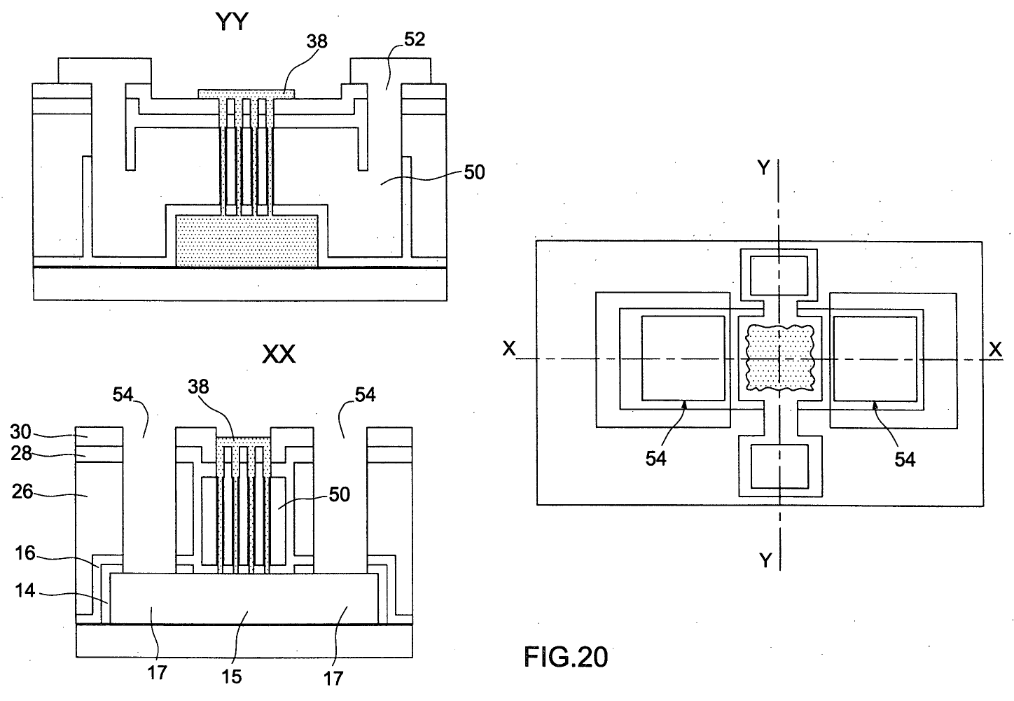

The next step (FIG. 20) preferably comprises the following operations: photolithography to define apertures 54 for access to the drain contact regions 17 on either side of the drain region 15. These apertures 54 are etched out by vertical anisotropic etching in the layer 30 (oxide), the layer 28 (nitride), the layer 26 (oxide), the layer 16 (nitride) and the layer 14 (oxide) in succession. The apertures bare the silicon of the island for the purpose of forming a drain contact in the regions 17.

Drain implantation is still possible at this stage. If this is necessary, a final deoxidation operation removes the silicon oxide present on the drain contact regions inside the apertures 50 and on the source 38.

A metal (titanium, tantalum, tungsten, etc.) layer may then be deposited and an annealing operation carried out, which produces an alloy (metal silicide) between the silicon and this metal on the surface 38, on the drain contact regions 17 in the apertures 54 and also on the gate contacts 52 that are flush with the surface. The unalloyed metal may be removed from the silicidation zones using a selective product that etches the metal without etching the silicide.

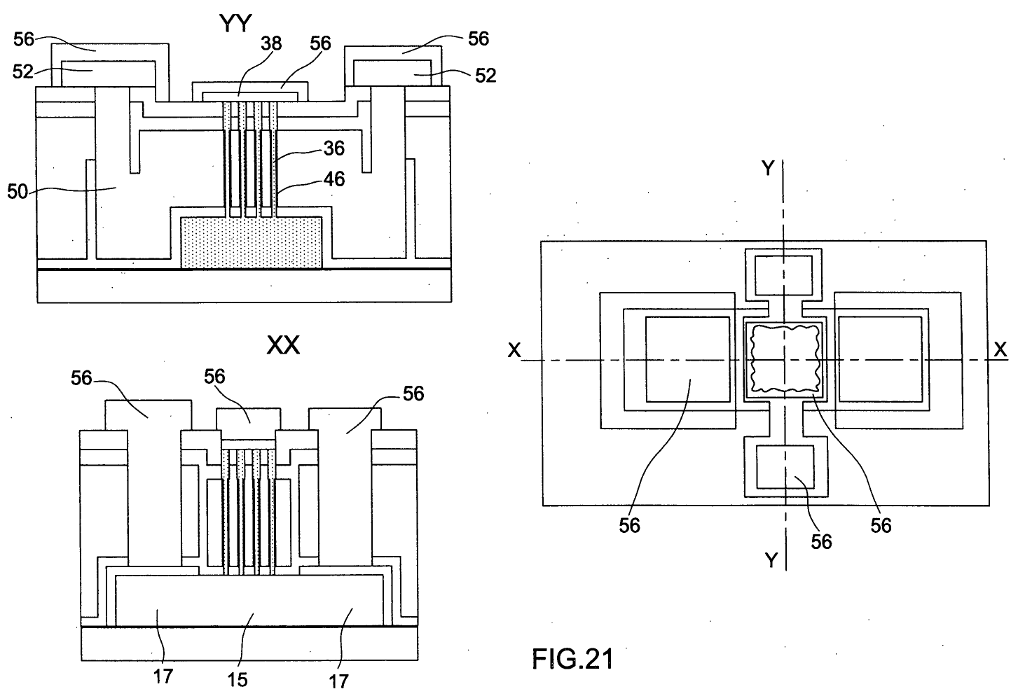

The final step consists in providing the desired interconnects for connecting the source, the gate and the drain of the vertical transistor thus produced to other circuit elements. This step (possibly divided into substeps) may be carried out by processes conventionally used in microelectronics. FIG. 21 shows simple interconnects made from a metal 56 deposited:
in the apertures 54, in contact with the drain 15;
on top of the source 38; and
on top of the gate contacts 52,
   the deposited metal being etched in a pattern corresponding to the desired interconnects between this transistor and other circuit elements.

Production of the interconnects could also involve more complete steps, such as the deposition of an insulating layer with a thickness greater than the existing layers, the opening of holes into this layer above the source 38, drain 17 and gate 52 contacts, the deposition of metal in the holes and outside the holes, and the etching of this metal according to the desired pattern of interconnects.

In an alternative embodiment of the invention, a sacrificial gate layer 18 made of silicon oxide, and not polycrystalline or amorphous silicon, is formed. In this case, the vertical holes 32 are drilled directly by an electron beam so as to reach the silicon surface of the drain region, that is to say, referring to FIG. 10, the holes 32 also pierce the nitride layer 16.

The lightly doped silicon constituting the semiconductor channels of the transistor are then grown by epitaxy. These channels are not surrounded by a thin insulating sheath, as in FIG. 13, but they are embedded in the entire sacrificial gate layer 18 of silicon oxide.

The next steps, explained with reference to FIGS. 14, 15 and 16, are not modified except that the etchants for etching the sacrificial gate layer are adapted so that this layer is made of silicon oxide. The semiconductor channels between source and gate are then formed by small-diameter vertical columns passing through a cavity by the removal of the layer 18.

Then, by isotropic deposition of an insulator or by thermal oxidation, an insulating sheath similar to the sheath 46 of FIG. 17 is formed around each channel. A space remains free between the adjacent channels thus sheathed with insulator. This space will subsequently be filled with the definitive conducting gate. An oxide is also deposited on top of the source 38.

The following steps are unchanged.

With the process according to the invention it is possible to produce simultaneously on the same silicon island, two transistors of opposite type, namely an NMOS and a pMOS transistor, having their drains electrically connected and their gates electrically connected, while having their sources separate. Such an assembly is used to make an inverter based on two complementary transistors, or a CMOS inverter.

To do this, the same fabrication principle is employed, but the holes in the sacrificial gate are drilled in two steps, namely in a first step holes are drilled above only one half of the drain region 15 and, in a second step holes above the other half of the drain region are drilled. The holes of the first half will serve to form the channels of the nMOS transistor and the holes in the second half will serve to form the channels of the pMOS transistor (or vice versa).

After having drilled the holes in the first half, and before the epitaxial growth of silicon in these holes, n-type (or p-type) impurities are introduced into the first half of the drain region by ion implantation through the holes that overhang them. Then, after the step explained with reference to FIG. 14 (i.e. after growth of the epitaxial silicon of the channels and the source and after the source 38 has been covered with an oxide 40), a second series of holes are opened, this time on top of the second half of the drain region. Before the epitaxial silicon is grown in these holes, impurities of the opposite type, p-type (or n-type), are introduced into the second half of the drain region by ion implantation through the holes that overhang them. After the epitaxial silicon has been grown in the channels and in the source of the second transistor, a step similar to that of FIG. 14 is repeated, namely the deposition of a thin insulating layer that covers the source of the second transistor. Finally, the steps explained with reference to FIGS. 15 et seq. are repeated in order to remove the sacrificial gate layer, to insulate the channels with a sheath and to reform a definitive gate in the cavity left by the sacrificial gate.

The sacrificial gate could also be made of silicon nitride.

The definitive gate may be made of doped polycrystalline silicon or made of titanium nitride, or made of a silicon/tungsten alloy or a silicon/germanium alloy.

The invention makes it possible to produce a transistor whose channel length is very well controlled since it is defmed by the thickness of the layer 18, the current through which is very well controlled since the channel is subdivided into many small-diameter channels each surrounded by a thin insulating sheath and individually encapsulated by a conducting control gate.

In the invention, the gate insulator is deposited at the end of the technological process, whereas the source and drain regions are already defined—it undergoes neither etching nor cleaning, thereby guaranteeing its quality. It is neither contaminated nor pierced.

In general, it should be noted that if the semiconductor island 12 is made of silicon, the channels may in principle be made of silicon. If the island is made of germanium, the channels will in principle be made of germanium. However, it is also conceivable for the island to be made of silicon and the channels to be made of a silicon/germanium compound, for example, an SiGe alloy containing 24% germanium.

1. A method for fabricating a vertical field-effect transistor comprising the following steps:
a) an island of semiconductor material, forming a drain region laterally adjacent to a drain contact region, is defined;
b) at least one layer, called a sacrificial gate layer, the thickness of which defines the length of the channels that separate the drain region from a source region lying above the drain region, is deposited;
c) several vertical holes are drilled in the sacrificial gate layer, above the drain region and down to the surface of the semiconductor material of this region;
d) a semiconductor material is epitaxially grown in the holes from the semiconductor material of the drain region, in order to form both vertical single-crystal semiconductor channels and the source region of the transistor;
e) the source region is doped;
f) the sacrificial gate layer is removed, leaving said channels of semiconductor material between the source region and the drain region, in a cavity surrounding these channels, and an insulating sheath is formed around each channel;
g) the cavity is filled with a conducting material forming a definitive gate isolated from the channels by the insulating sheaths; and
h) interconnects in contact with the drain contact region, with the source region and with the definitive gate are formed.

2. A method according to claim 1, wherein step b) includes the deposition of an insulating layer especially a silicon nitride or silicon oxide or germanium nitrite layer, before the deposition of the sacrificial gate layer, and the deposition of an insulating layer after the deposition of the sacrificial gate layer.

3. A method according to claim 1, wherein the sacrificial gate layer is etched in step b) so as to cover the drain region and a gate contact region external to the island of semiconductor material, but not the drain contact region.

4. A method according to claim 1, wherein a step of depositing an insulating planarization layer is carried out after the sacrificial gate layer has been etched, before step c).

5. A method according to claim 1, wherein the drilling of step c) uses an electron beam lithography.

6. A method according to claim 1, wherein the material of the definitive gate is doped polycrystalline silicon, or titanium nitride or a silicon/tungsten alloy or a silicon/germanium alloy.

7. A method according to claim 1, wherein the material of the sacrificial gate layer is polycrystalline silicon.

8. A method according to claim 7, wherein step c) of drilling holes is followed by a step of oxidizing the silicon of the sacrificial gate inside the holes before step d) of epitaxial silicon growth.

9. A method according to claim 8, wherein step f) of removing the sacrificial gate layer comprises the removal of the oxide formed after drilling the holes, followed by deposition of a very thin layer of insulation, preferably silicon oxide, forming an individual insulating sheath around each channel.

10. A method according to claim 1, wherein the material of the sacrificial gate layer is silicon oxide or silicon nitride.

11. A method according to claim 1, wherein two transistors of opposite type, namely NMOS and pMOS, having a common drain contact, a common gate contact and separate source contacts, are formed on a single island of semiconductor material.

12. Vertical field-effect transistor comprising an island of doped single-crystal semiconductor material comprising a drain region and a drain contact region placed laterally with respect to the drain region, and, above the island, two source regions and two separate source contact, and two groups of several vertical parallel channels made of a lightly-doped single-crystal semiconductor material, one group N-doped, the other group P-doped, which extend vertically between the drain region and one respective source region, each channel being completely surrounded by an insulating sheath, and the space separating the channels thus isolated from one another being filled with a conducting gate each surrounding the channels.

13. Vertical field-effect transistor according to claim 12, wherein the gate extends above the drain region but not above the drain contact region.

14. Vertical field-effect transistor according to claim 13, wherein the gate region includes at least two extensions that extend laterally outside the drain and drain contact regions.
